(19) United States
(12) Patent Application Publication
(10) Pub. No.: US 2022/0193677 A1
(43) Pub. Date: Jun. 23, 2022

(54) FOLDABLE DIGITAL MICROFLUIDIC (DMF) DEVICE USING FLEXIBLE ELECTRONIC PLATFORM AND METHODS OF MAKING SAME

(71) Applicant: Nicoya Lifesciences, Inc., Kitchener (CA)

(72) Inventor: Gordon H. Hall, Milton (CA)

(21) Appl. No.: 17/440,024

(22) PCT Filed: Mar. 20, 2020
(86) PCT No.: PCT/CA2020/050372

§ 371 Date: Sep. 16, 2021

Related U.S. Application Data
(60) Provisional application No. 62/821,512, filed on Mar. 21, 2019.
(60) Provisional application No. 62/861,182, filed on Jun. 13, 2019.

(51) Int. Cl. B01L 3/00; G01N 21/552

(52) U.S. Cl. CPC B01L 3/502792; G01N 21/553; B01L 2200/12; B01L 2300/123; B01L 2300/0883; B01L 2300/0645

(57) ABSTRACT

A foldable digital microfluidic (DMF) device using a flexible electronic platform and methods of making same is disclosed. The foldable DMF device includes a flexible polyimide substrate with thin copper features that is foldable to provide opposing substrates. The foldable DMF device further includes a flexible polyimide dielectric layer also with thin copper features. In some embodiments, the structure for forming the presently disclosed foldable DMF device is based on the use of blind vias. In some embodiments, the foldable DMF device includes one droplet actuation layer. In other embodiments, the foldable DMF device includes multiple droplet actuation layers. Additionally, a method of making the foldable DMF device is provided.

### CROSS REFERENCE TO RELATED APPLICATIONS

The present application is a U.S. national stage entry under 35 U.S.C. § 371 of PCT Application No. PCT/CA2020/050372 filed on 20 Mar. 2020 entitled “FOLDABLE DIGITAL MICROFLUIDIC (DMF) DEVICE USING FLEXIBLE ELECTRONIC PLATFORM AND METHODS OF MAKING SAME,” which claims benefit of priority to U.S. Provisional Patent Application No. 62/861,182 filed on 13 Jun. 2019 entitled “FOLDABLE DIGITAL MICROFLUIDIC (DMF) DEVICE USING FLEXIBLE ELECTRONIC PLATFORM AND METHODS OF MAKING SAME” and U.S. Provisional Patent Application No. 62/821,512 filed on 21 Mar. 2019 entitled “FOLDABLE DIGITAL MICROFLUIDIC (DMF) DEVICE USING FLEXIBLE ELECTRONIC PLATFORM AND METHODS OF MAKING SAME,” each of the foregoing being specifically incorporated by reference herein for all that they disclose or teach.

### TECHNICAL FIELD

The presently disclosed subject matter relates generally to microfluidic devices for performing assays and more particularly to a foldable digital microfluidic (DMF) device using a flexible electronic platform and methods of making same.

### BACKGROUND

In digital microfluidics technology, the digital microfluidic (DMF) devices are often printed circuit board (PCB)-based DMF devices or cartridges (also called droplet actuators). For example, a PCB-based substrate is arranged opposite a glass or plastic substrate. The PCB-based substrate may include an arrangement of droplet operations electrodes (e.g., electrowetting electrodes). The glass or plastic substrate may include a ground reference electrode that is substantially optically transparent, such as an indium tin oxide (ITO) ground reference electrode. There is a gap between the PCB-based substrate and the glass or plastic substrate. The gap may be filled with filler fluid (e.g., silicone oil) or air and droplet operations can occur in the gap. Examples of droplet operations can include, but are not limited to, droplet transporting, droplet splitting, droplet merging, droplet mixing, droplet agitating, droplet diluting, and the like.

There are certain drawbacks with conventional DMF devices or cartridges or droplet actuators. For example, they can be complex and costly to fabricate. Namely, conventional DMF devices may include two substrates that must be precisely assembled together and also connected electrically. Further, a PCB-based substrate may have limitations with respect to dielectric uniformity and surface flatness. These limitations may result in performance problems such as limited droplet transport velocities, reduced droplet actuation reliability, and requiring higher electrowetting voltages.

### SUMMARY

The present disclosure relates to flexible digital microfluidics (DMF) devices. The DMF devices described herein may utilize a flexible electronics platform or substrate, which may facilitate advantages in relation to the manufacture and/or operation of the DMF device.

In some embodiments, the presently disclosed subject matter provides a foldable digital microfluidic (DMF) device using a flexible electronic platform and methods of making same. Namely, the presently disclosed foldable DMF device may include a flexible substrate that is foldable to provide opposing substrates. In certain embodiments, the flexible substrate may comprise a flexible polyimide substrate. Accordingly, the “bottom” substrate (and its features) and the “top” substrate (and its features) of the DMF device may share a common substrate, which may be a flexible and foldable polyimide substrate. This enables simultaneous processing of either “top” or “bottom” aspects of the DMF device during manufacture. Further, the presently disclosed foldable DMF device may include the flexible polyimide substrate as well as a flexible polyimide dielectric layer. Additionally, either or both of the flexible polyimide substrate and the flexible polyimide dielectric layer may include thin copper features. Further, the presently disclosed foldable DMF device may include multiple flexible polyimide layers with copper to provide, for example, multiple routing, wiring, and/or shielding layers. In particular, droplet actuation electrodes and the necessary electrical connections for operation thereof may be formed in a conductive material (e.g., copper) to facilitate droplet operations once the DMF device has been folded into a desired configuration. Moreover, one or more ground plane electrodes, which may facilitate operation of the droplet actuation electrodes may be formed. In any regard, multiple copper layers are provided, separated by polyimide and adhesive.

In some embodiments, the presently disclosed foldable DMF device may be a U-shaped foldable DMF device that has one droplet actuation layer.

In some embodiments, the presently disclosed foldable DMF device may be a serpentine-shaped foldable DMF device that has multiple droplet actuation layers.

In some embodiments, the presently disclosed foldable DMF device may be a serpentine-shaped foldable DMF device that has multiple droplet actuation layers and that has substantially the same footprint as the single-chamber U-shaped foldable DMF device.

In some embodiments, the structure for forming the presently disclosed foldable DMF device may be based on the use of blind vias. In yet other embodiments, the structure for forming the presently disclosed foldable DMF device may be based on the use of through-hole vias.

Further, as compared with conventional DMF devices, the presently disclosed foldable DMF device that includes the blind via-based structure may include a thinner copper layer (e.g., about 2 μm vs 35+ μm for conventional), thinner dielectric (e.g., polyimide layer about 12.7 μm (0.5 mils) thick), only one dielectric layer, and/or flatter more uniform surfaces.

Further, as compared with conventional DMF devices, the presently disclosed foldable DMF device lends well to improved DMF droplet movement (higher velocities, more reliable actuation, lower electrowetting voltage) by facilitating a thinner, more uniform dielectric and flatter surfaces. Namely, a method of making the presently disclosed foldable DMF devices is provided, which may be a top-down process that may begin with a thin polyimide substrate (i.e., the dielectric) with no adhesive that results in flatter DMF devices with thinner dielectric and better performance as compared with conventional DMF devices.

Further, the presently disclosed foldable DMF device may include a folding mechanism that can reduce the part-count per device, simplify fabrication, and reduce device cost as compared with conventional DMF devices.

### BRIEF DESCRIPTION OF THE DRAWINGS

The features and advantages of the present disclosure will be more clearly understood from the following description taken in conjunction with the accompanying drawings, which are not necessarily drawn to scale, and wherein:

FIG. 1 illustrates a side view of an example of a DMF structure on which the presently disclosed foldable DMF device is based;

FIG. 2 illustrates a side view of an example of a flexible structure prior to folding for forming the presently disclosed foldable DMF device;

FIG. 3 illustrates a top view and a side view of the flexible structure shown in FIG. 2 after folding and forming a U-shaped foldable DMF device having one droplet actuation layer;

FIG. 4 illustrates a side view of an example of the presently disclosed foldable DMF device when in use;

FIG. 5 illustrates a side view of an example of the presently disclosed foldable DMF device with stiffeners installed;

FIG. 6 illustrates a side view of the DMF structure shown in FIG. 1 and a method of accessing electrically any electrode thereof when a stiffener is present;

FIG. 7 illustrates a side view of another example of a flexible structure prior to folding for forming the presently disclosed foldable DMF device;

FIG. 8 illustrates a side view of the flexible structure shown in FIG. 5 after folding and forming a serpentine-shaped foldable DMF device having two droplet actuation layers;

FIG. 9 illustrates a side view of another example of a serpentine-shaped foldable DMF device having multiple droplet actuation layers;

FIG. 10 illustrates a flow diagram of an example of a method of making the presently disclosed foldable DMF device; and

FIG. 11 illustrates a side view of another example of a DMF structure for forming the presently disclosed foldable DMF device.

### DETAILED DESCRIPTION

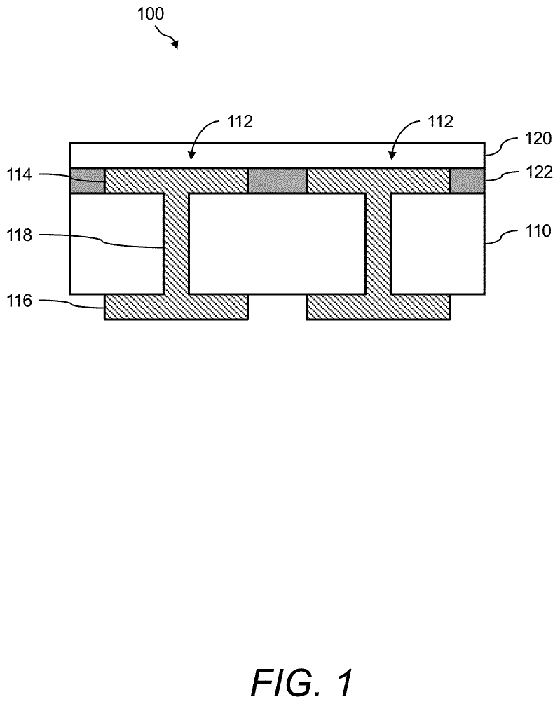

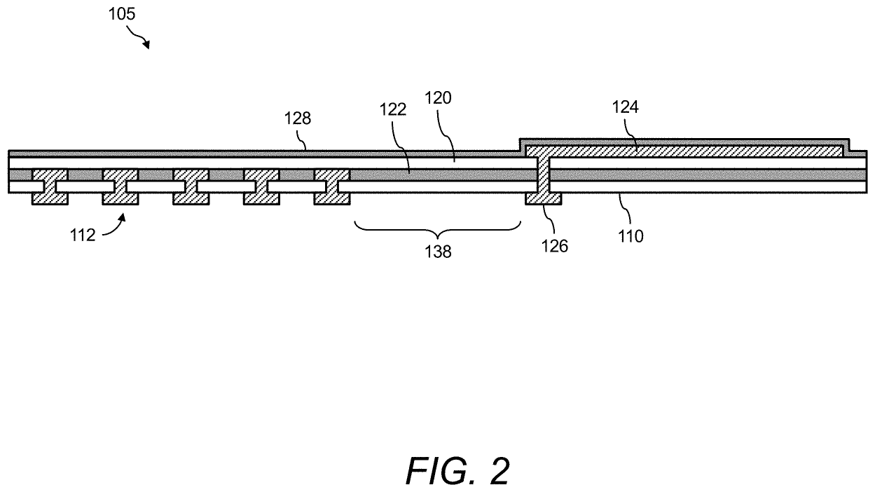

FIG. 1 shows a side view of an example of a DMF structure 100 on which the presently disclosed foldable DMF device is based. In this example, DMF structure 100 is a structure based on the use of blind vias. For example, DMF structure 100 can be the basis for forming the presently disclosed foldable DMF devices 200 shown in FIG. 2 through FIG. 9.

DMF structure 100 may include a polyimide substrate 110 that may further include an arrangement of droplet operations electrodes 112 that may be formed using a blind-via technique. For example, the droplet operations electrodes 112 may include an actuation electrode 114 on one side of polyimide substrate 110 and an outer electrode 116 on the opposite side of polyimide substrate 110. Then, respective ones of the actuation electrode 114 and outer electrode 116 may be electrically connected using a blind via 118 that passes through the thickness of polyimide substrate 110. In one example, polyimide substrate 110 is about 12.7 μm (0.5 mils) thick. Actuation electrodes 114 and outer electrodes 116 may be, for example, copper electrodes that are about 2 μm thick. Likewise, blind vias 118 may be columns of copper having a diameter of, for example, about 100 μm. Droplet operations electrodes 112 are not limited to copper. Droplet operations electrodes 112 can be formed, for example, of copper, gold, silver, aluminum, and the like.

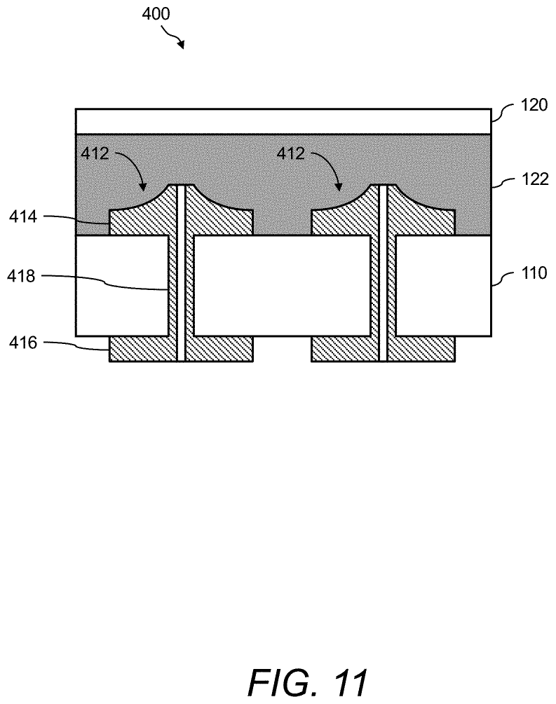

The use of blind vias 118, as compared with through-hole vias (see FIG. 11), allows the surfaces of actuation electrodes 114 and outer electrodes 116 to be highly flat, uniform, and planar. The mechanism that enables this is that blind-vias (e.g., blind vias 118) mean the top electrodes (e.g., actuation electrodes 114) do not get electroplated during the via plating process. Atop actuation electrodes 114 in DMF structure 100 is a polyimide dielectric layer 120 that is, for example, about 12.7 μm (0.5 mils) thick. The polyimide dielectric layer 120 may be flexible, and is therefore interchangeably referred to herein as the flexible polyimide dielectric layer 120. The polyimide dielectric layer 120 that has an adhesive layer 122 may be laminated atop actuation electrodes 114. Generally, the thickness of the polyimide substrate 110 and the polyimide dielectric layer 120 can be the same or can be different. In one example, both polyimide substrate 110 and polyimide dielectric layer 120 are about 12.7 μm thick. In another example, polyimide substrate 110 is thicker than polyimide dielectric layer 120. For example, polyimide substrate 110 is about 25 μm thick and polyimide dielectric layer 120 is about 12.7 μm thick.

In the presently disclosed foldable DMF devices 200, DMF structure 100 may facilitate (1) a highly uniform surface due to the presence of flat and thin electrodes, and (2) lower electrowetting voltages as compared with conventional DMF devices or cartridges or droplet actuators due to the thin dielectric layer. Because the force applied to a droplet in an electrowetting device is inversely proportional to the thickness of the dielectric and proportional to the square of the voltage, the presently disclosed foldable DMF devices 200 may use lower voltage to perform droplet operations as compared with conventional DMF devices. Further, the lower electrowetting voltage in the presently disclosed foldable DMF devices 200 reduces electrical complexity and increases DMF device and instrumentation electronics lifetime as compared with conventional DMF devices. More details of examples of the presently disclosed foldable DMF device using DMF structure 100 are shown and described hereinbelow with reference to FIG. 2 through FIG. 9.

FIG. 2 shows a side view of an example of a flexible structure 105 prior to folding for forming the presently disclosed foldable DMF device 200. Flexible structure 105 may include the flexible polyimide substrate 110, which is, for example, a polyimide sheet that may be about 12.7 μm (0.5 mils) thick. An arrangement of droplet operations electrodes 112 may be provided at one portion (e.g., at one end) of flexible structure 105. Further, polyimide dielectric layer 120 may be laminated atop droplet operations electrodes 112 using adhesive layer 122. A ground reference electrode (or plane) 124 may be provided at another portion (e.g., at the other end and/or in non-overlapping relation with the droplet operation electrodes 112 in the unfolded configuration depicted in FIG. 2) of flexible structure 105 and atop polyimide dielectric layer 120. A ground contactor 126 may be provided for electrical connection to ground reference electrode 124. A hydrophobic layer 128 may be provided atop ground reference electrode 124 and any exposed portion of polyimide dielectric layer 120. Hydrophobic layer 128 may be, for example, a single hydrophobic spray coat that can be used for forming the presently disclosed foldable DMF device 200.

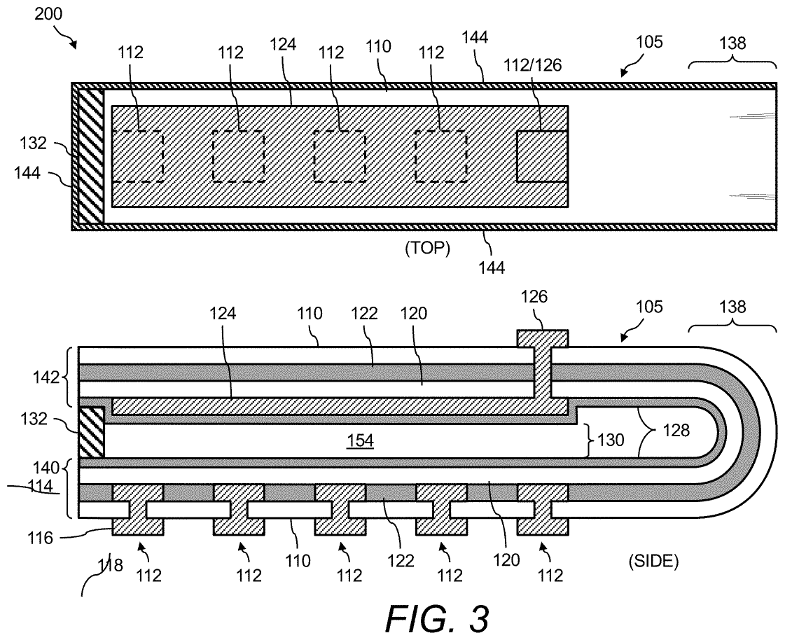

Flexible structure 105 may have a folding region 138 between the arrangement of droplet operations electrodes 112 and ground reference electrode 124. For example, to form foldable DMF device 200, the flexible polyimide substrate 110 may be folded with droplet operations electrodes 112 and ground reference electrode 124 folding toward one another. Accordingly, when flexible structure 105 is folded at folding region 138, the arrangement of droplet operations electrodes 112 may be opposite ground reference electrode 124 as shown in FIG. 3.

FIG. 3 shows a top view and a side view of the flexible structure 105 shown in FIG. 2 after folding and forming a U-shaped foldable DMF device 200 having one droplet actuation layer. For example, in foldable DMF device 200, droplet operations electrodes 112 may be arranged substantially opposite the ground reference electrode 124. Further, the plane of droplet operations electrodes 112 may be substantially parallel to the plane of ground reference electrode 124. In one example, a lower portion 140 of foldable DMF device 200 may include droplet operations electrodes 112 whereas an upper portion 142 of foldable DMF device 200 may include ground reference electrode 124. Lower portion 140 and upper portion 142 of foldable DMF device 200 may be separated by a droplet operations gap 130 to form a droplet actuation layer 154. The height of droplet operations gap 130 may be set by the bend in folding region 138 and/or a spacer 132 between the now opposing ends of flexible structure 105. In one example, spacer 132 can be one or more conventional pillars formed of, for example, additional layers of polyimide or as a template of plastic. In another example, spacer 132 can be a precision solder spacer disk, such as the TrueHeight® Spacer Blocks available from Alpha Assembly Solutions (Somerset, N.J.). In foldable DMF device 200, the gap height can be from about 10s of microns to 100s of microns.

The sides of foldable DMF device 200 may be sealed, for example, by an adhesive compound or by mechanical force that holds the lower portion 140 and upper portion 142 together. In one example, this adhesive is an ultraviolet (UV)-cured adhesive and foldable DMF device 200 is sealed on three sides. For example, an adhesive layer 144 may be “wrapped” around foldable DMF device 200 starting at a first side, then the non-folded end opposite the folding region, and then a second side opposite the first side as shown, for example, in the top view of FIG. 3.

The terms “top,” “bottom,” “upper,” “lower,” “over,” “under,” “in,” and “on” are used throughout the description with reference to the relative positions of components of the presently disclosed foldable DMF devices, such as the relative positions of lower portion 140 and upper portion 142 of foldable DMF device 200. It will be appreciated that the foldable DMF device is functional regardless of its orientation in space.

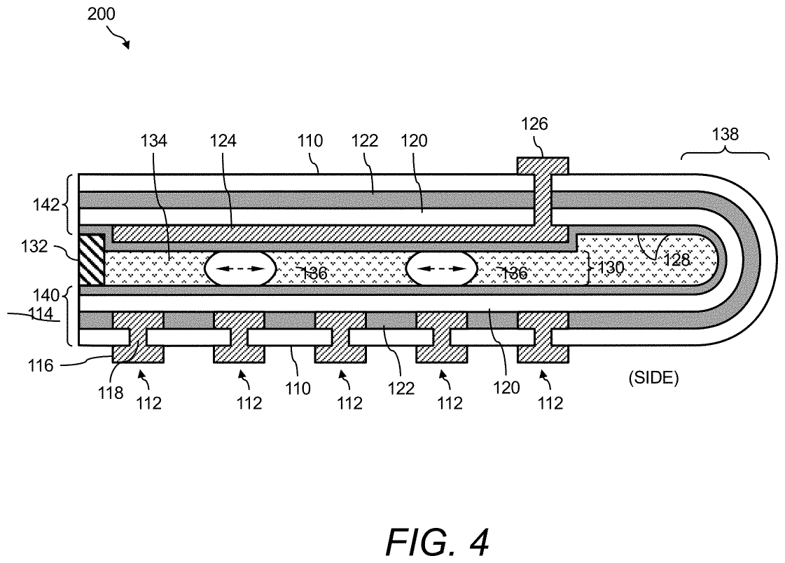

FIG. 4 shows a side view of the foldable DMF device 200 shown in FIG. 3 when in use. In this example, droplet actuation layer 154 may be filled with a filler fluid 134. Filler fluid 134 may, for example, be or include a low-viscosity oil, such as silicone oil or hexadecane filler fluid. One or more droplets 136 may be in droplet operations gap 130 in droplet actuation layer 154. Droplets 136 may, for example, be aqueous or non-aqueous or may be mixtures or emulsions including aqueous and non-aqueous components. Droplet operations may be conducted atop droplet operations electrodes 112 on a droplet operations surface. In this example, droplet operations are conducted in filler fluid 134. In another example, droplet actuation layer 154 may be filled with air instead of filler fluid 134 and droplet operations are conducted in air. Further still, droplets 136 may be provided in an “oil-shell” in the actuation layer 154. That is, a filler fluid 134 such as an oil may be provided in a coating about at least a portion, if not substantially surrounding, the droplet 136.

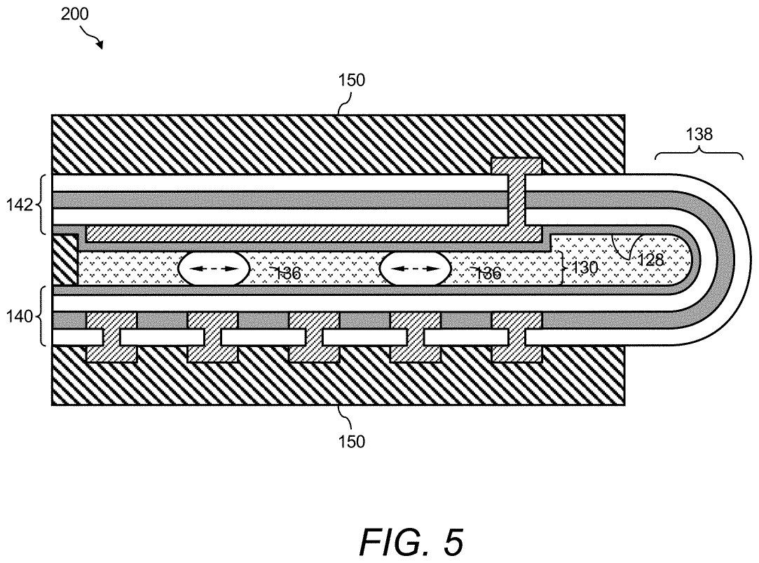

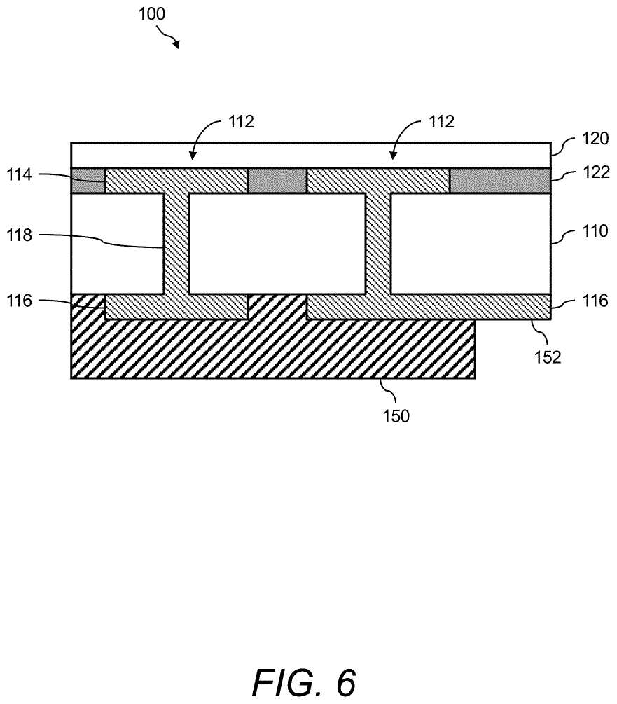

FIG. 5 shows a side view of an example of the presently disclosed foldable DMF device 200 with stiffeners installed. To assist with holding flatness and/or rigidity, disclosed foldable DMF device 200 may include a stiffener 150 against one or both sides. For example, one stiffener 150 may be provided against lower portion 140 of foldable DMF device 200 and another stiffener 150 may be provided against the upper portion 142 of foldable DMF device 200. Stiffeners 150 may be formed, for example, of glass or plastic. In another example, stiffeners 150 may be a standard rigid PCB material, such as FR4. Further to the example, FIG. 6 shows a method of accessing electrically any electrode of foldable DMF device 200 when a stiffener 150 is present. For example and showing again the DMF structure 100, a portion of outer electrode 116 of droplet operations electrode 112 may extend beyond the edge of or into an opening of stiffener 150. Accordingly, an electrode access 152-portion of outer electrode 116 is provided.

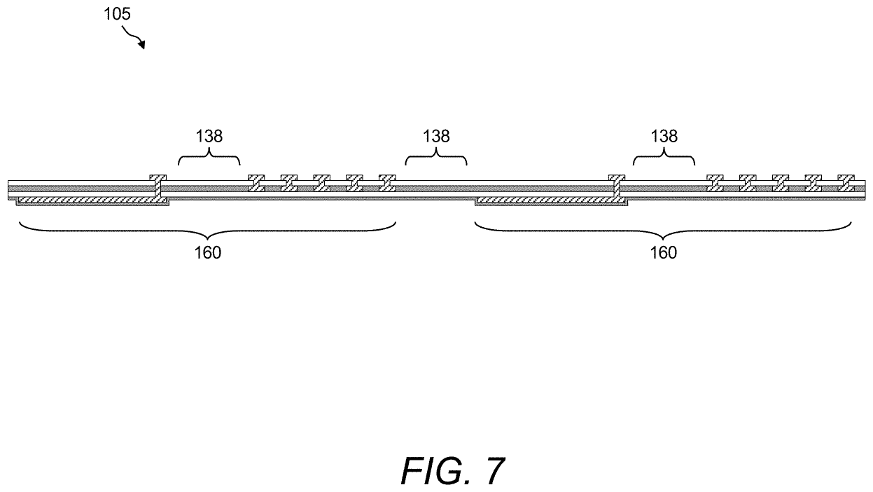

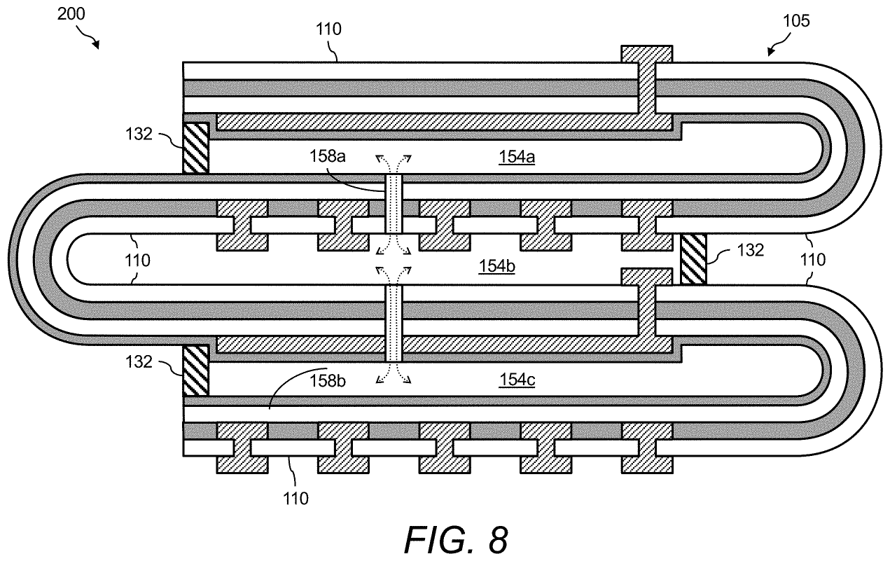

FIG. 7 shows a side view of another example of a flexible structure 105 prior to folding for forming the presently disclosed foldable DMF device 200. In this example, flexible structure 105 may include a plurality of segments that comprise repeating pattern 160 and multiple folding regions 138 between adjacent instances of the segments comprising the repeating pattern 160 for forming the serpentine-shaped foldable DMF device 200 shown in FIG. 8. Namely, FIG. 8 shows a side view of a serpentine-shaped foldable DMF device 200 having three droplet actuation layers 154 (e.g., droplet actuation layers 154a, 154b, 154b). The serpentine-shaped foldable DMF device 200 may further include one or more flow channels 158 for providing fluid connection between the three droplet actuation layers 154. That is, one or more droplet actuation layers may be connected by a flow channel for establishing fluid communication therebetween. For example, a flow channel 158a may fluidly connect droplet actuation layer 154a to droplet actuation layer 154b. Additionally, a flow channel 158b fluidly connects droplet actuation layer 154b to droplet actuation layer 154b. Multiple spacers 132 may be provided for setting the gaps of and defining the boundaries of the reaction (or assay) chambers of the various droplet actuation layers.

A serpentine-shaped foldable DMF device 200 may facilitate certain beneficial features. In one example, the flow channels 158 may allow fluid to be transported between tiers (e.g., droplet actuation layers 154a, 154b, 154b). Accordingly, serpentine-shaped foldable DMF device 200 can be used to effectively double or triple the amount of active area as, for example, the single tier U-shaped foldable DMF device 200 shown in FIG. 3, FIG. 4, and FIG. 5 while maintaining the same footprint. In another example, the mirrored droplet operations electrodes 112 that are shared between droplet actuation layer 154a and droplet actuation layer 154b allow multiplexing of the experiment (e.g., for alternative investigations and/or for use of reference sensors). In yet another example, sensor spots (not shown) can overlap so that one detection location can serve multiple analyses.

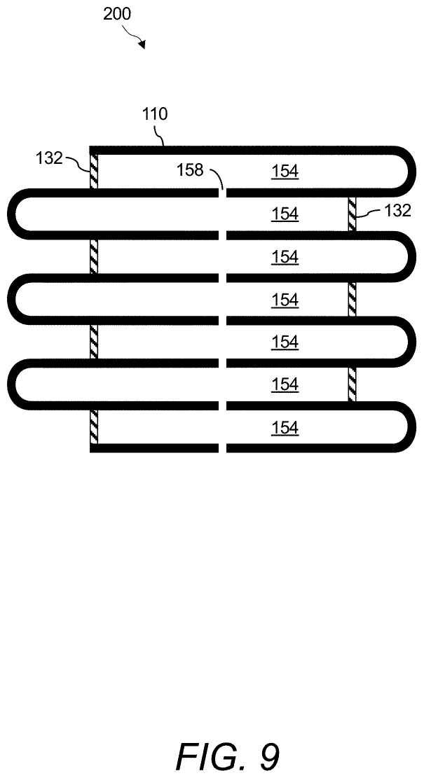

FIG. 9 shows a side view of another example of a serpentine-shaped foldable DMF device 200 having multiple droplet actuation layers 154. The serpentine-shaped foldable DMF device 200 can include any number of droplet actuation layers 154 that are fluidly connected by flow channels 158.

In the presently disclosed foldable DMF devices 200 described hereinabove with reference to FIG. 1 through FIG. 9, the polyimide layers and copper layers may not be optically transparent. Accordingly, optical detection methods may not lend well to foldable DMF devices 200. However, other detection methods are possible with foldable DMF devices 200. In this regard, a sensor may be provided that is positioned relative to the foldable DMF device such that the sensor is disposed for measurement of the foldable DMF device. In one example, detection can be accomplished using a sensor comprising an infrared (IR) camera capable of imaging through the polyimide layers and/or copper layers. In another example, a sensor may comprise capacitive feedback can be used that is operative to monitor droplet movements. Another method of detection may be to interface a sensor with the fluid from the side or edge of the device. For example, a sensor comprising an optical fiber with a chemical sensor on the tip may be introduced from the side of edge into the fluid to perform analyses. such as surface plasmon resonance.

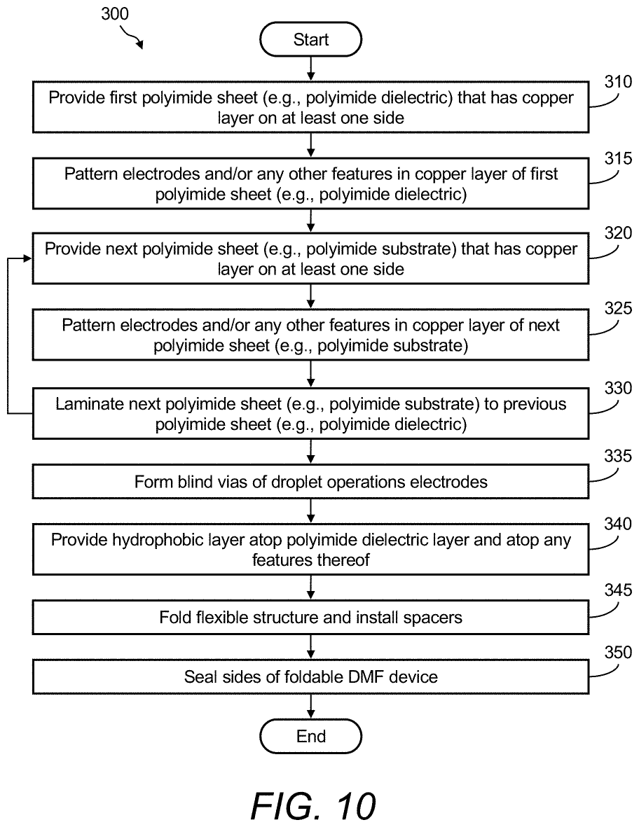

Conventional DMF devices are typically made using a bottom-up process (i.e., bottom substrate to top substrate) in which the dielectric layer (e.g., polyimide) is laminated at the end of the process. However, this process requires a thick adhesive layer to perform the lamination of the dielectric layer. The thick dielectric/adhesive layer results in a certain amount of dielectric nonuniformity and surface roughness that adversely effects performance. By contrast, a method of making the presently disclosed foldable DMF devices is provided, which may be a top-down process that begins with a thin polyimide substrate (i.e., the dielectric) with no adhesive that facilitates a flatter DMF devices with thinner dielectric and better performance as compared with conventional DMF devices. By way of example, FIG. 10 shows a flow diagram of an example of a method 300 of making the presently disclosed foldable DMF devices 200. A main benefit of method 300 is that it enables simultaneous processing of either or both “top” and/or “bottom” aspects of the presently disclosed foldable DMF devices 200. Method 300 may include, but is not limited to, the following steps.

At a step 310, a sheet may be provided that can be used with the top-down process described in method 300. The sheet may include a substrate layer and a conductive material layer. For instance, the substrate layer may comprise a flexible substrate layer, which may be a polyimide sheet. The conductive material layer may comprise a thin copper layer on at least one side of the polyimide sheet. For example, polyimide sheets are available from Panasonic Corporation, DowDuPont Incorporated and many other suppliers. In one example, a 12.7 μm (0.5 mils)-thick polyimide sheet that has a 5 μm-thick copper layer on one side is provided. In another example, a 12.7 μm (0.5 mils)-thick polyimide sheet that has a 2 μm-thick copper layer on both sides is provided. In this example, one of the 2 μm-copper layers may be removed. For example, an etching process can be used to remove this copper layer. In so doing, a polyimide sheet is provided that has a 2 μm-thick copper layer on one side only. The polyimide portion of the resulting sheet is the flexible polyimide dielectric layer 120 of foldable DMF devices 200.

At a step 315, electrodes and/or any other features are patterned in the thin copper layer on one side of the polyimide sheet provided in step 310. For example, using standard photolithography and/or etching processes, actuation electrodes 114 of droplet operations electrodes 112 are patterned in the 2 μm-thick or 5 μm-thick copper layer on one side of this polyimide sheet, which is flexible polyimide dielectric layer 120.

At a step 320, another sheet may be provided. This sheet may also comprise a substrate layer comprising a polyimide sheet that has a conductive material layer (e.g., a thin copper layer) on at least one side is provided. Again, polyimide sheets are available from Panasonic Corporation and DowDuPont Incorporated among other suppliers. In one example, a 12.7 μm (0.5 mils)-thick polyimide sheet that has a 5 μm-thick copper layer on one side is provided. In another example, a 12.7 μm (0.5 mils)-thick polyimide sheet that has a 2 μm-thick copper layer on both sides is provided. In this example, one of the 2 μm-copper layers may be removed. For example, an etching process can be used to remove this copper layer. In so doing, a polyimide sheet is provided that has a 2 μm-thick copper layer on one side only. In another example, this polyimide sheet that is about 25 μm thick. The polyimide portion of the resulting sheet is the flexible polyimide substrate 110 of foldable DMF devices 200. In foldable DMF devices 200, the exposed side (non-copper side) of this polyimide sheet (i.e., polyimide substrate 110) is facing the patterned side (copper side) of the first polyimide sheet (i.e., polyimide dielectric layer 120) provided in step 310.

At a step 325, electrodes and/or any other features are patterned in the thin copper layer on one side of the polyimide sheet provided in step 320. For example, using standard photolithography and/or etching processes, outer electrodes 116 of droplet operations electrodes 112 are patterned in the 2 μm-thick or 5 μm-thick copper layer on one side of this polyimide sheet, which is flexible polyimide substrate 110.

At a step 330, the polyimide sheet (i.e., polyimide substrate 110) provided in steps 320 and 325 is laminated to any previously provided polyimide sheets, such as the polyimide sheet (i.e., polyimide dielectric layer 120) provided in steps 310 and 315. For example, the exposed side (i.e., the non-copper side) of polyimide substrate 110 has an adhesive layer 122 that is laminated to the side of polyimide dielectric layer 120 that has and actuation electrodes 114.

Additionally, steps 320, 325, and 330 may be repeated multiple times to form any stack of multiple copper layers for, for example, routing, wiring, and/or shielding purposes, and wherein the layers are laminated via corresponding adhesive layers (e.g., adhesive layer 122).

At a step 335, the blind vias are formed in droplet operations electrodes 112. For example, openings or columns that correlate to the positions of the blind vias 118 are patterned in the stack of outer electrodes 116, polyimide substrate 110, and actuation electrodes 114 (see FIG. 1) but not through the polyimide dielectric layer 120. Further, the openings or columns may reach but not penetrate actuation electrodes 114. For example, using standard photolithography, etching, and/or drilling processes using conventional or laser drills, openings or columns that correlate with the positions of blind vias 118 are patterned in the stack of outer electrodes 116, polyimide substrate 110, and actuation electrodes 114. Then, using standard PCB processes, copper may be deposited, electroplated, or otherwise provided in the openings to form blind vias 118 and thereby electorally connect respective ones of the outer electrode 116 to a corresponding actuation electrode 114 to form the droplet operations electrode 112.

At a step 340, a hydrophobic layer is provided atop the polyimide dielectric layer and atop any features thereof. For example, hydrophobic layer 128 is provided atop ground reference electrode 124 and any exposed portion of polyimide dielectric layer 120. Namely, hydrophobic layer 128 can be applied via a hydrophobic spray coating. A benefit of the presently disclosed foldable DMF devices 200 is that only one spray coating may be used for both the “bottom” and “top” substrates of the finished foldable DMF devices 200. At the completion of this step, flexible structure 105, such as shown in FIG. 2 and FIG. 7, is formed.

At a step 345, the flexible structure is folded and spacers are installed. For example and referring again to FIG. 2 and FIG. 7, flexible structure 105 is folded over on itself at any one or more of the folding regions 138. Namely, any fold occurs by folding the arrangement of droplet operations electrodes 112 toward its corresponding ground reference electrode 124 such that, once folded, the arrangement of droplet operations electrodes 112 is opposite its corresponding ground reference electrode 124 as shown, for example, in FIG. 3 and FIG. 8. Next, one or more spacers 132 are installed to set the gaps of and define the boundaries of the reaction (or assay) chambers of the various droplet actuation layers (e.g., one or more droplet actuation layers 154).

At a step 350, the sides of the foldable DMF device are sealed. For example, the sides of the foldable DMF device 200 shown in FIG. 3 or FIG. 8 are sealed using an adhesive compound or by mechanical means that holds the lower portion 140 and upper portion 142 together. In one example, this adhesive is a UV-cured adhesive and foldable DMF device 200 is sealed on three sides. For example and referring again to the top view of FIG. 3, adhesive layer 144 is “wrapped” around foldable DMF device 200 starting at one side, then the non-folded end, and then the other side. An example of UV-cured epoxy suitable for adhesive layer 144 is EPO-TEK® OG675 available from Epoxy Technology, Inc (Billerica, Mass.). The thickness of adhesive layer 144 can be, for example, about 300 μm.

FIG. 11 shows a side view of another example of a DMF structure 400 for forming the presently disclosed foldable DMF device 200. In this example, DMF structure 400 may be a structure based on the use of through-hole vias. For example, DMF structure 400 can be the basis for forming the presently disclosed foldable DMF devices. DMF structure 400 may include a polyimide substrate 110 as described with reference to DMF structure 100 of FIG. 1. In DMF structure 400, polyimide substrate 110 may include an arrangement of droplet operations electrodes 412 that may be formed using through-hole vias. The polyimide substrate 110 may be referred to herein interchangeably as the flexible polyimide substrate 110. For example, the droplet operations electrode 412 may include an actuation electrode 414 on one side of polyimide substrate 110 and an outer electrode 416 on the opposite side of polyimide substrate 110. Then, actuation electrode 414 and outer electrode 416 are electrically connected using a through-hole via 418 that passes through the thickness of polyimide substrate 110. Droplet operations electrodes 412 may be formed, for example, of copper.

The method for forming DMF structure 400 may include laminating layers of polyimide with copper, drilling the through-holes, and then plating the electrodes and through-holes. Finally, a thin polyimide dielectric layer 120 may be laminated atop actuation electrode 414 using adhesive layer 122. Namely, DMF structure 400 may formed using the conventional bottom-up process (i.e., bottom substrate to top substrate) in which polyimide dielectric layer 120 is laminated at the end of the process. However, this process requires a thick adhesive layer 122 to perform the lamination of polyimide dielectric layer 120.

While the presently disclosed foldable DMF devices, such as the foldable DMF devices 200 shown in FIG. 2 through FIG. 9, can be formed using DMF structure 400, there are certain differences as compared with DMF structure 100 of FIG. 1. For example, the actuation electrodes 414 of DMF structure 400 are much larger and/or thicker than the actuation electrodes 114 of DMF structure 100. This adds surface roughness and/or surface nonuniformity as compared with the surface of DMF structure 100. This may further result in the adhesive layer 122 of DMF structure 400 being significantly thicker than the adhesive layer 122 of DMF structure 100. This, in turn, affects the electrowetting behavior. For example, DMF structure 400 may use a higher electrowetting voltage as compared with DMF structure 100.

In summary and referring now again to FIG. 1 through FIG. 11, foldable DMF devices 200 are provided that are formed according to method 300 of FIG. 10 using a flexible electronic platform, such as flexible polyimide substrate 110 in combination with flexible polyimide dielectric layer 120. In the presently foldable DMF devices 200, flexible polyimide substrate 110 and flexible polyimide dielectric layer 120 are foldable to provide opposing substrates. Namely, the lower portion 140 (or “bottom” substrate) and the upper portion 142 (or “top” substrate) of the DMF device 200 share a common substrate, which is flexible polyimide substrate 110. Namely, method 300 enables simultaneous processing of either or both “top” and/or “bottom” aspects of the presently disclosed foldable DMF devices 200. Additionally, either or both flexible polyimide substrate 110 and flexible polyimide dielectric layer 120 may include thin copper features.

What is claimed is:

1. A foldable digital microfluidics (DMF) device, comprising:
a flexible substrate;
a plurality of droplet operations electrodes disposed on at least a first side of the flexible substrate at a first portion of the flexible substrate;
a ground reference electrode disposed on at least the first side of the flexible substrate at a second portion of the flexible substrate; and
a folding region disposed between the first portion of the flexible substrate and the second portion of the flexible substrate.

2. The foldable DMF device of claim 1, further comprising:
a dielectric layer on at least the first side of the flexible substrate that extends relative to the first portion atop an actuation electrode portion of the plurality of droplet operations electrodes.

3. The foldable DMF device of claim 2, wherein the ground reference electrode is disposed atop the dielectric layer.

4. The foldable DMF device of claim 1, further comprising:
a hydrophobic layer provided on the first side of the flexible substrate that extends at least relative to the first portion and the second portion of the flexible substrate.

5. The foldable DMF device of claim 1, wherein the device is configurable between:
a first configuration in which the first portion and the second portion are substantially coplanar; and
a second configuration in which the folding region is flexed to position the first portion opposite the second portion such that the first portion is separated from the second portion by a droplet operations gap to form a droplet actuation layer.

6. The foldable DMF device of claim 5, wherein when in the second configuration, the plurality of droplet operation electrodes of the first portion and the ground reference electrode of the second portion are substantially parallel.

7. The foldable DMF device of claim 5, wherein when in the second configuration, the DMF device is sealed on three sides comprising a first side portion and a second side portion on opposite sides of the DMF device in the second configuration and an end portion opposite the folding region.

8. The foldable DMF device of claim 5, wherein the droplet actuation layer comprises a filler fluid through which droplets are moveable.

9. The foldable DMF device of claim 5, wherein the droplet actuation layer comprises and air gap through which the droplets are moveable.

10. The foldable DMF device of claim 5, wherein droplets in the droplet actuation layer comprise an oil shell surrounding at least a portion of the droplet.

11. The foldable DMF device of claim 5, further comprising:
a sensor disposed for measurement of fluid in the foldable DMF device when in the second configuration.

12. The foldable DMF device of claim 11, wherein the sensor is operative to monitor droplet movement in the droplet actuation layer.

13. The foldable DMF device of claim 11, wherein the sensor comprises a surface plasmon resonance (SPR) sensor.

14. The foldable DMF device of claim 13, wherein the SPR sensor is disposed at a tip of an optical fiber disposed in the droplet actuation layer.

15. The foldable DMF device of claim 1, wherein the flexible substrate comprises:
a repeating pattern of a plurality of segments each comprising an instance of the first portion and an instance of the second portion separated by a folding region; and
a serpentine folding region between the plurality of segments.

16. The foldable DMF device of claim 15, wherein each instance of the repeating pattern are foldable at the folding region between the instance of the first portion and the instance of the second portion such that the first portion is separated from the second portion by a droplet operations gap to form a droplet actuation layer, and wherein the serpentine folding region is foldable such that adjacent instances of the repeating pattern are separated by a droplet operations gap to form a plurality of droplet actuation layers.

17. The foldable DMF device of claim 16, wherein each of the plurality of droplet actuation layers are connected by flow channel establishing fluid communication therebetween.

18. The foldable DMF device of claim 1, wherein the flexible substrate comprises polyimide.

19. The foldable DMF device of claim 1, wherein the droplet operation electrodes comprise an actuation electrode on the first side of the flexible substrate and an outer electrode on a second side of the flexible substrate opposite the first side, the actuation electrode being electrically connected to the outsider electrode by a blind via.

20. A method for top-down method of manufacture of a foldable digital microfluidics device, comprising:
providing a dielectric layer having a first conductive material layer on a at least a first side thereof, forming a plurality of actuation electrodes from the first conductive material layer;
providing a flexible substrate layer having a second conductive material layer on at least a first side thereof;
forming a plurality of outer electrodes from the second conductive material layer;
laminating the dielectric layer to the flexible substrate layer such that a second side of the flexible substrate layer opposite the first side of the flexible substrate layer contacts the first side of the dielectric layer to form a foldable DMF structure; and
folding the foldable DMF structure at a folding region defined between a ground plane electrode and a plurality of droplet operation electrodes comprising the plurality of actuation electrodes and the plurality of outer electrodes to dispose the ground plane electrode and the plurality of droplet operation electrodes on opposite sides of a droplet operations gap to form a droplet actuation layer.

21. The method of claim 20, wherein the method further comprises:
forming a blind via between respective ones of the actuation electrodes and the outer electrodes to establish electrical communication therebetween.

22. The method of claim 20, further comprising:
applying a hydrophobic layer to a second side of the dielectric layer opposite the first side of the dielectric layer, wherein the hydrophobic layer is disposed on opposite sides of the droplet actuation layer after the folding step.

23. The method of claim 20, wherein the dielectric layer comprises a third conductive material layer on the second side of the dielectric layer, and the method further comprises:
forming a ground plane electrode from the third conductive material layer.
